(19) United States
(12) Patent Application Publication
(10) Pub. No.: US 2010/0203747 A1
(43) Pub. Date: Aug. 12, 2010

(54) FLEXIBLE PRINTED CIRCUIT BOARD HAVING EMBOSSED CONTACT ENGAGING PORTION

(75) Inventors: NAN HU, Shenzhen (CN); HAN-MING ZHANG, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION INDUSTRY CO., LTD., Tu-Cheng (TW)

(21) Appl. No.: 12/576,252

(22) Filed: Oct. 9, 2009

(30) Foreign Application Priority Data
Feb. 9, 2009 (CN) 200910300370.6

(51) Int. Cl. H01R 12/00; H05K 1/00

(52) U.S. Cl. 439/77; 174/254

(57) ABSTRACT

A flexible printed circuit board (20) for electrically connecting an insulator substrate (21) and a plurality of elongate conductors (21a) laminated over the insulator substrate by an upper layer. The conductor has a contact engaging portion (211a) exposed over the insulator substrate at end thereof. The contact engaging portion (211a) defines an embossed portion (212) for engaging against the mating component.

### BACKGROUND OF THE INVENTION

1. Field of the Invention

The present invention relates to a flexible printed circuit board (FPC), and more particularly, to a FPC having embossed contact engaging portion ensuring reliable and robust electrical interconnection.

2. Description of the Related Art

FPC is a medium used for data transmission between computers and the peripherals connected thereto or within a printer in which the printing head is interconnected with a control unit with the FPC such that the printing head is free to oscillate along a rack during printing process. FPC is typically formed using a process in which several elongate conductors such as copper foils are deposited uniformly and parallel over a flexible insulator substrate. A protective mask in a desired pattern is then applied to the conductor. In use, only the protective mask is removed for interconnection with connector or the like. CN Pat No. 2766378 issued to Guo on Mar. 22, 2006, discloses a conventional FPC used in a camera socket for transmitting data converted from an image taken by a camera module to a storage device within a mobile phone or the like. The FPC defines a plurality of contact terminals connecting with bottom of the camera module. The camera socket has a resilient bracket biasing the FPC to press against the module.

Normally, the signal terminals of the FPC and a corresponding contact engaging portion defined by the camera module are both flattened for interconnecting with each other steadily. However the contact terminals could have burrs at edges thereof in manufacturing process, resulting poor and improper interconnection therebetween.

Therefore, an improved FPC is desired to overcome the disadvantages of the related arts.

### SUMMARY OF THE INVENTION

An object of the present invention is to provide a flexible printed circuit board providing conductors with embossed contact engaging portion to ensure reliable electrical interconnection with mating component.

In order to achieve the above-mentioned object, A flexible printed circuit board for electrically connecting an insulator substrate and a plurality of elongate conductors laminated over the insulator substrate by an upper layer. The conductor has a contact engaging portion exposed over the insulator substrate at end thereof. The contact engaging portion defines an embossed portion for engaging against the mating component.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a perspective view of a FPC made in accordance with the preferred embodiment of the present invention;

FIG. 2 is a perspective view of a camera socket assembly showing said FPC of FIG. 1 received therein;

FIG. 3 is a perspective view showing a camera module assembled into a camera socket in which the FPC made in according to the present invention is applied;

FIG. 4 is an exploded view of a camera socket in which the FPC made in accordance with the present invention is properly disclosed;

FIG. 5 is similar to FIG. 4, while taken from a reversed direction;

FIG. 6 is a cross-sectional view of the camera socket assembly taken along line 6-6 of FIG. 3 but showing the camera module in ghost line;

FIG. 7 is an enlarged view taken from encircled portion from FIG. 5;

FIG. 8 is a perspective view of a FPC made in accordance with a second embodiment of the present invention;

FIG. 9 is a perspective view of a FPC cable assembly in which the FPC shown in FIG. 8 is applied therein; and

FIG. 10 is a cross-sectional view of the FPC cable assembly taken along line 10-10 of FIG. 9.

### DETAILED DESCRIPTION OF THE INVENTION

Reference will now be made to the drawing figures to describe the preferred embodiment of the present invention in detail.

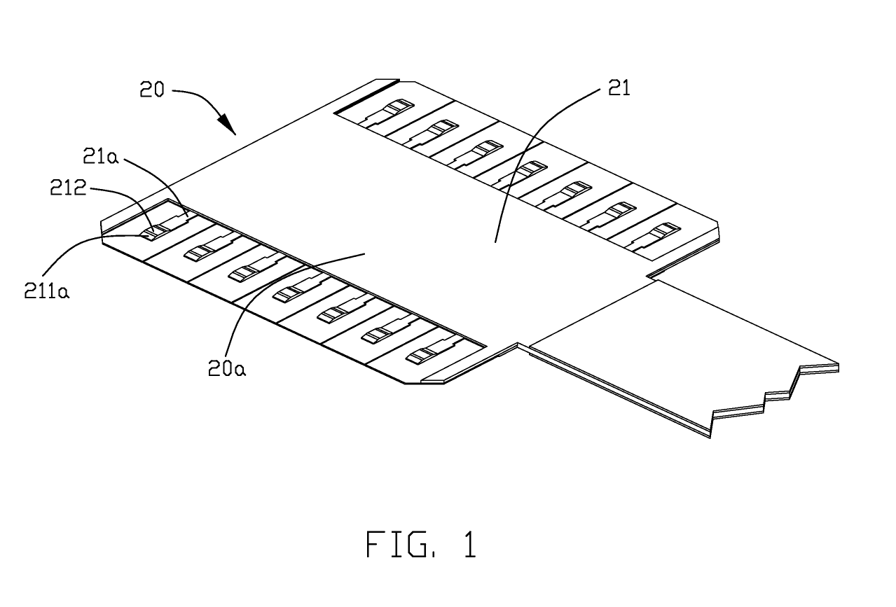

Referring to FIG. 1, a FPC 20 of the present invention is formed using a process in which several elongate conductors 21a such as copper foils are laminated uniformly and parallel over a flexible insulator substrate 21 by an upper layer 20a. In use, a section of the upper layer 20a is peeled off from an end such that the conductors 21a are exposed, and these exposed conductors 21a serve as a contact engaging portion 211a for interconnecting with other components such as golden fingers on a printed circuit board serves. Each of the conductors 21a is provided with an embossed portion 212 to enhance the interconnection.

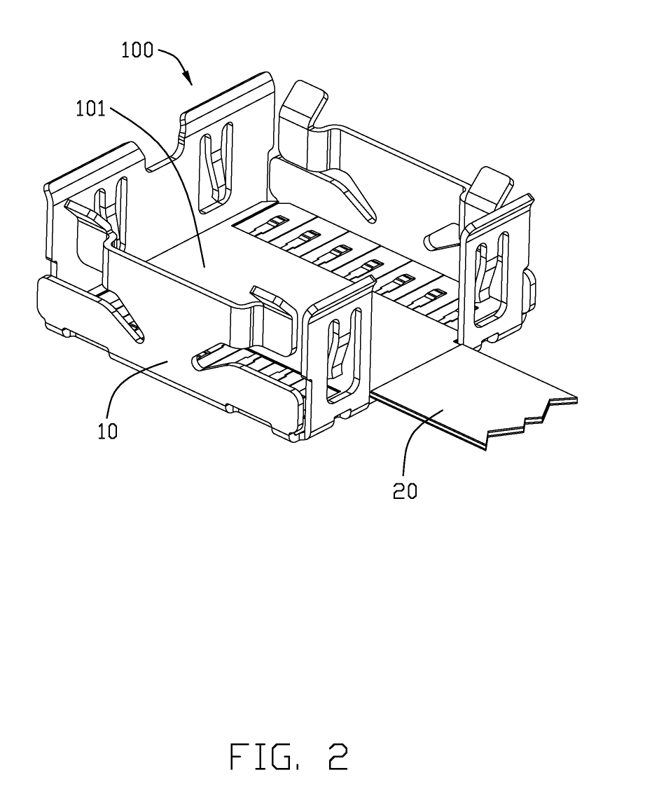

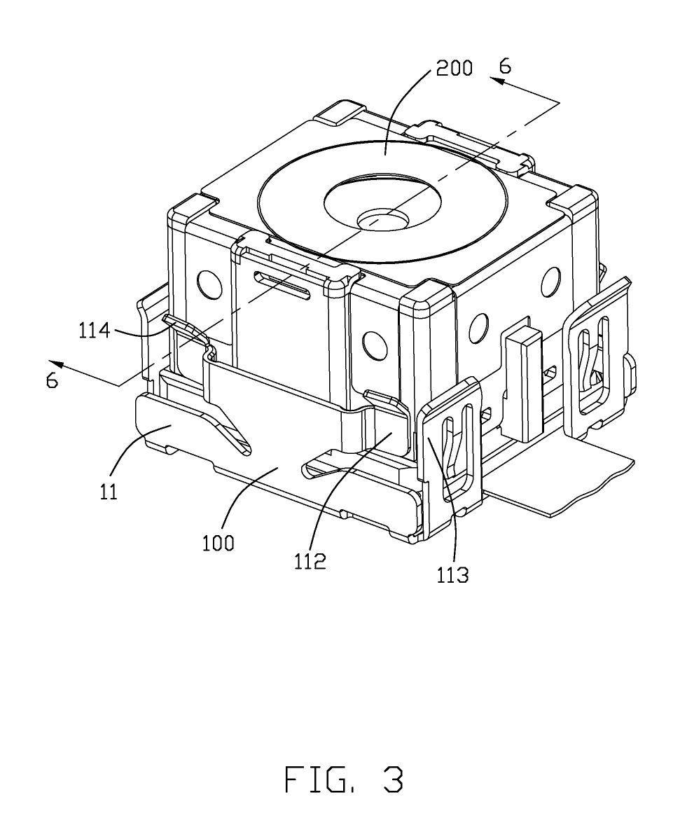

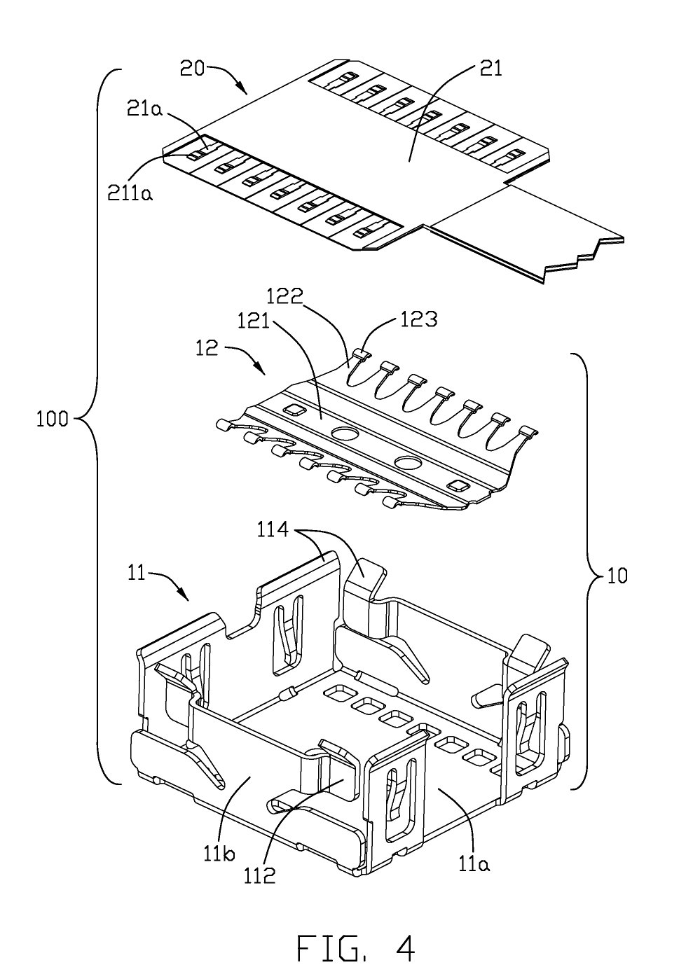

Referring to FIGS. 2 to 4, said FPC 20 made in accordance with the present invention is now disposed and located within a camera socket unit 10 thereby configuring a camera socket 100. The camera socket 100 defines a receiving room 101 for receiving a camera module 200 therein. The socket unit 10 includes a metallic shell 11. The metallic shell 11 defines a bottom wall 11a and side walls 11b extending upwards from periphery of the bottom wall perpendicular to the bottom wall 11a, thereby forms said receiving room 101. The socket unit 10 farther has a resilient bracket 12 located in the receiving room 101 and mechanically anchored to the bottom wall 11a. The resilient bracket 12 is made of metal and includes a body portion 121 soldered to the bottom wall 11a and a plurality of fingers 122 respectively extend slantways and upwardly from both side of the body portion 121.

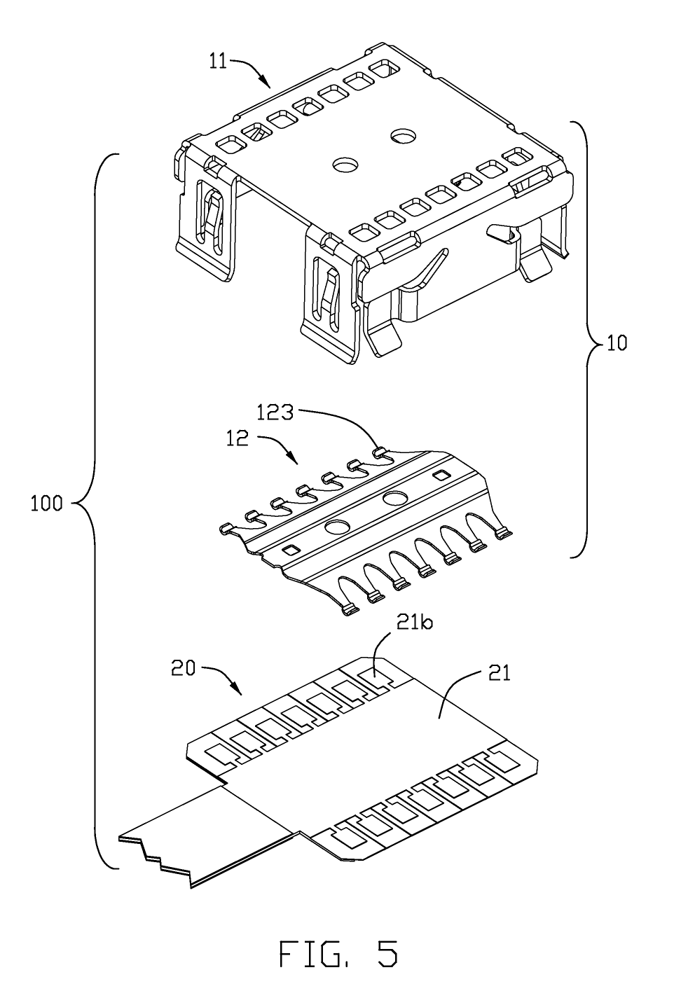

The FPC 20 is seated upon the resilient bracket 12 such that each of the embossed portions 212 is supported by the corresponding finger 122 of the resilient bracket 12. Along with FIG. 5, said FPC 20 defines a plurality of grounding pads 21b at bottom side thereof for mechanically engaging with the fingers 122 of the resilient bracket 12 thereby establishing a grounding path for preventing the socket 100 from Electrometric Interference (EMI).

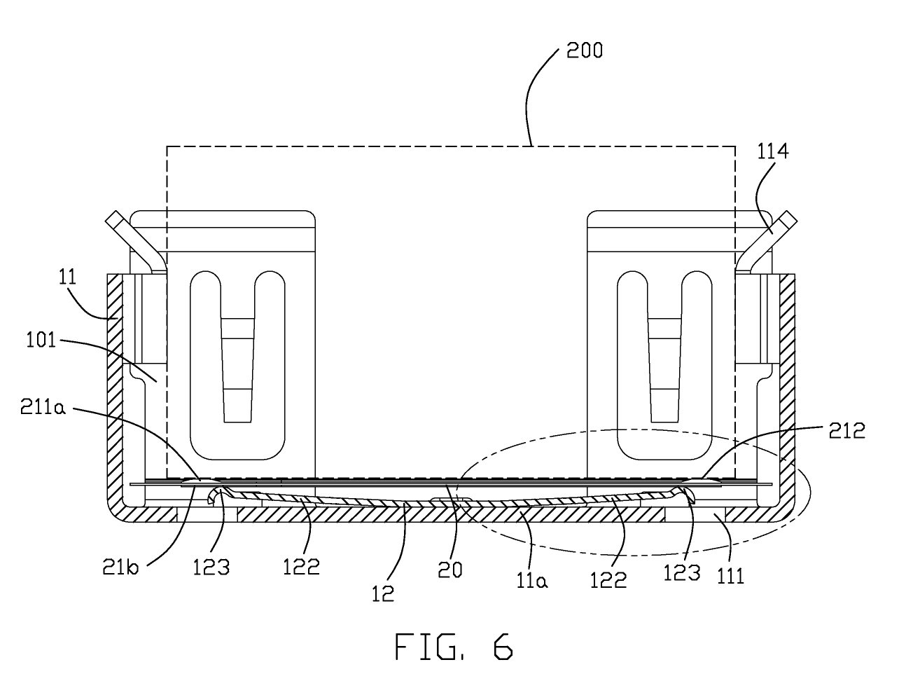

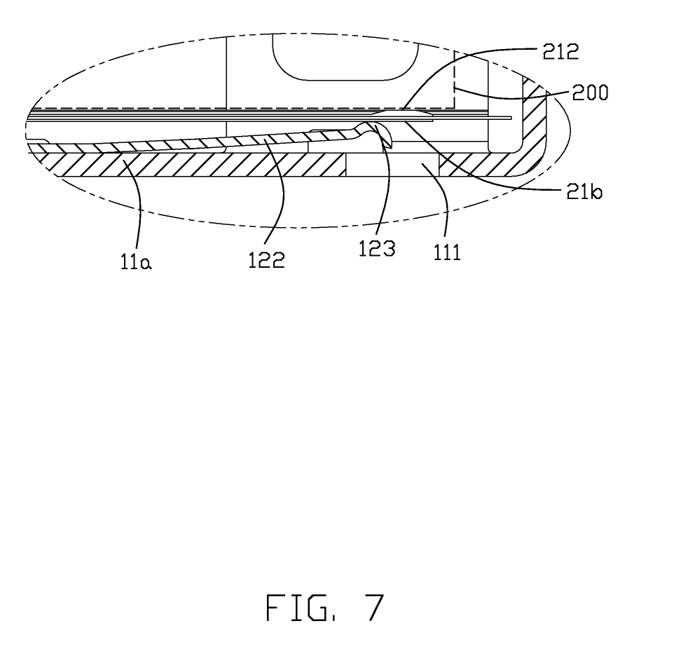

Referring to FIGS. 6 and 7, when the camera module 200 is disposed into the receiving room 101 along an up-to-down direction and securely seated therein, the FPC 20 is sandwiched between the camera module 200 and the resilient bracket 12 of the socket unit 10. The finger 122 has an engaging portion 123 at free end thereof upholding the FPC 20 and elastically distorted downwards by pressure of camera module 200. Therefore, the FPC 20 could electrically and reliably interconnect to the camera module 200 for transmitting data converted from an image taken by the camera module 200. Correspondingly, the bottom wall 11a of the shell is provided with a plurality of holes 111 to provide an extension for said engaging portions 123.

The FPC 20 is upheld and urged by the resilient bracket 12, so that the embossed portions 212 engage with a plurality of electrical conductors defined under the camera module 200. Because of the embossed portions 212 has a protruding surface, the contact engaging portion 211a could always in contact with the camera module 200 reliably and robustly, even if the FPC 20 is distorted and the contact engaging portion 211a is slant as a result of an upward reaction of said resilient bracket 12.

The camera module 200 has a rectangular base portion corresponding to the receiving room 101 and said electrical conductors for electrically connecting with the contact engaging portion of the flexible printed circuit board 20. The side walls 11b of the shell 11 define at least one of locking arms 112 for clamping on periphery of the module 200, a plurality of grounding portions 113 pressing towards the camera module 200 and electrically connecting to said grounding trace and a guiding portion 114 inclining outwards at top edge thereof which forms a rectangular bugle-shaped opening for guiding the camera module 200 inserting into the receiving room 101.

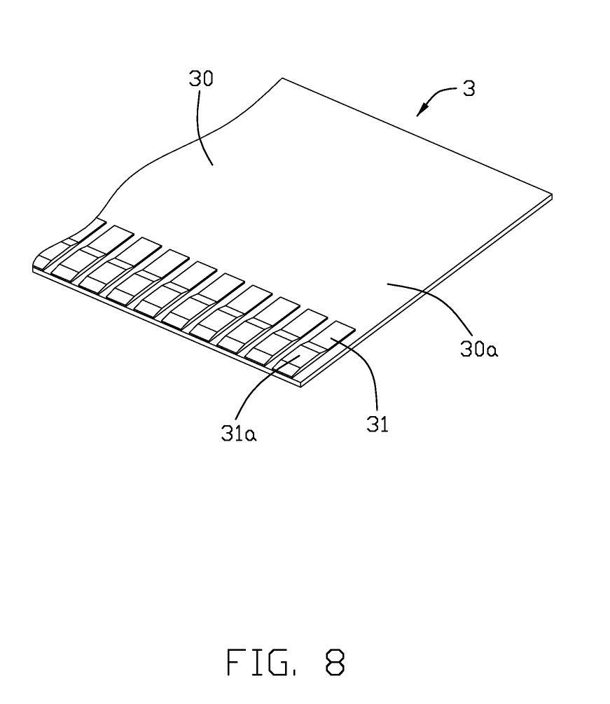

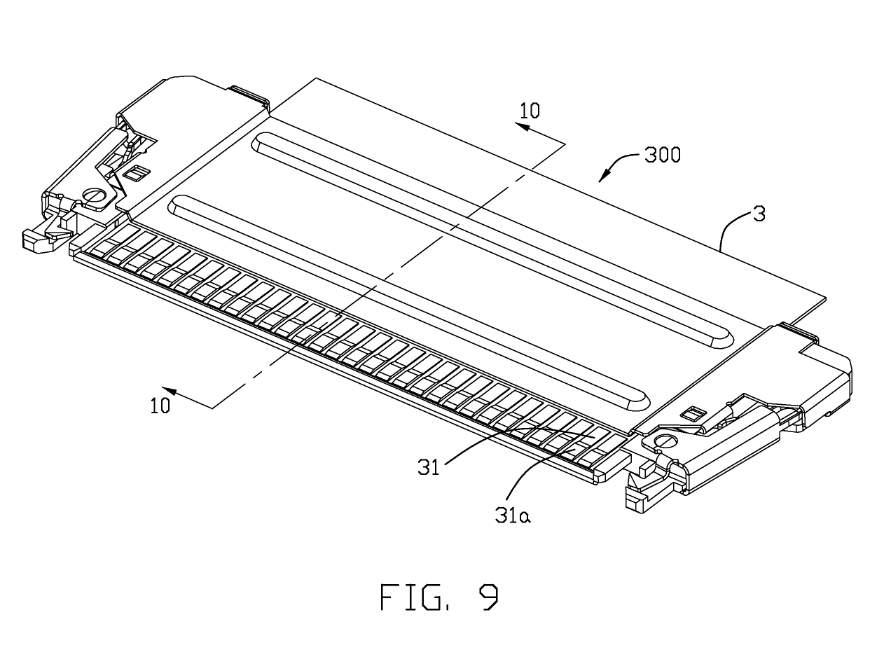

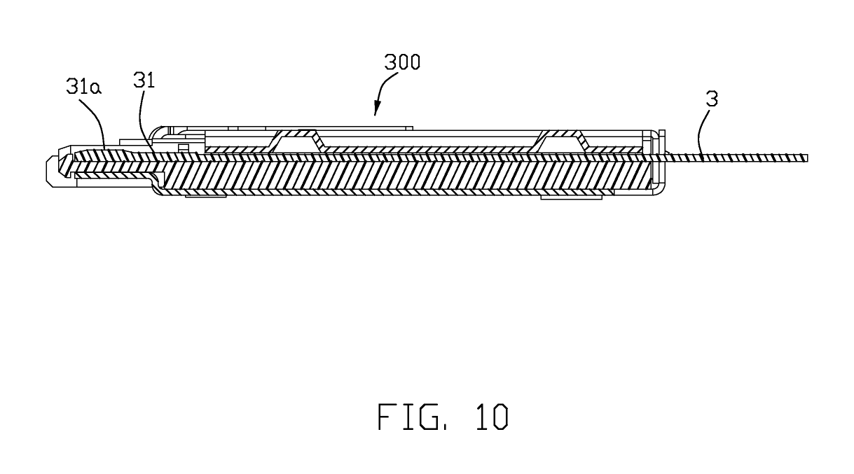

Referring FIGS. 8 to 10, another embodiment of FPC of the present invention is shown, which is applied in a LCD cable connector 300 that is differently configured from aforementioned camera socket 100 interconnecting with the camera module 200. The FPC 3 of this embodiment is also formed using a process in which several elongate conductors 31 such as copper foils are laminated uniformly and parallel over a flexible insulator substrate 30 by an upper layer 30a. In use, a section of the upper layer 30a is peeled off from an end such that the conductors 31 are exposed, and these exposed conductors 31 serve as a contact engaging portion for interconnecting with other components such as golden fingers on a printed circuit board serves. Each of the conductors 31 is provided with an embossed portion 31a to enhance the interconnection with corresponding mating component. The cable connector 300 is similar to current conventional LCD cable connector excepting for the FPC 3, therefore these normal structures are known by technical person in related field and not described.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the board general meaning of the terms in which the appended claims are expressed.

What is claimed is:

1. A flexible printed circuit board for electrically connecting with a mating component, comprising:
an insulator substrate and a plurality of elongate conductors laminated over the insulator substrate by an upper layer and comprising a contact engaging portion exposed over the insulator substrate at end thereof; and
wherein the contact engaging portion comprises an embossed portion for engaging against the mating component.

2. The flexible printed circuit board as described in claim 1, wherein the embossed portions are disposed at outermost end of the contact engaging portion.

3. The flexible printed circuit board as described in claim 2, wherein contact engaging portion comprise a foot portion of molded in the insulator substrate.

4. The flexible printed circuit board as described in claim 2, wherein each of the embossed portions includes two opposite inclined section at two opposite ends thereof, respectively.

5. An interconnecting system comprising:
a socket comprising a metallic shell forming a receiving room and a resilient bracket disposed in the receiving room and mechanical connecting with bottom of the shell;
a flexible printed circuit board seated upon the resilient bracket and comprising a contact engaging portion at one side thereof opposite to the spring element; and
a camera module received in the receiving room and disposed upon the flexible printed circuit, comprising a plurality of conductive pads corresponding to the contact engaging portions of the flexible printed circuit board;
wherein the contact engaging portion comprises an embossed portion protruding towards the camera module.

6. The interconnecting system as described in claim 5, wherein the resilient bracket comprises a plurality of fingers driving the embossed portion of the flexible printed circuit board engaging with the conductive pads of the camera module.

7. The interconnecting system as described in claim 6, wherein the resilient bracket comprises a body portion soldered to the metallic shell, said fingers extend slantways and upwardly from both sides of the body portion.

8. The interconnecting system as described in claim 6, wherein the shell comprises a bottom wall which defines a plurality of holes corresponding to the fingers of the resilient bracket to provide an extension for said fingers.

9. The interconnecting system as described in claim 9, wherein the camera module comprises a rectangle base received in the receiving room.

10. The interconnecting system as described in claim 5, wherein the shell comprises at least one of locking arms clamp on outside of the camera module.

11. The interconnecting system as described in claim 5, wherein the shell comprises a guiding portion inclining outwards at top edge thereof.

12. A camera socket comprising:
a metallic shell forming a receiving room for accepting a camera module;
a resilient bracket disposed in the receiving room and mechanical connecting with bottom of the metallic shell;
a flexible printed circuit board seated upon the resilient bracket and comprising a contact engaging portion at one side thereof opposite to the resilient bracket; and
wherein the contact engaging portion comprises an embossed portion for engaging against the camera module.

13. The camera socket as described in claim 12, wherein the resilient bracket comprises a plurality of fingers upholding the embossed portion of the flexible printed circuit board for engaging with the camera module.

14. The camera socket as described in claim 13, wherein the resilient bracket comprises a body portion soldered to the metallic shell, said fingers extend slantways and upwardly from both sides of the body portion.

15. The camera socket as described in claim 13, wherein the shell comprises a bottom wall which defines a plurality of holes corresponding to the fingers of the resilient bracket for providing an extension for said fingers.

16. The camera socket as described in claim 12, wherein the receiving room comprises a rectangle-shaped opening.

17. The camera socket as described in claim 12, wherein the shell comprises a guiding portion inclining outwards at top edge thereof.

18. The camera socket as described in claim 12, wherein the shell comprises a plurality of locking arms for clamping on outside of the module.
